(19) United States
(12) Patent Application Publication
(10) Pub. No.: US 2024/0017375 A1
(43) Pub. Date: Jan. 18, 2024

(54) SUBSTRATE PROCESSING SYSTEM AND SUBSTRATE PROCESSING METHOD

(71) Applicant: Tokyo Electron Limited, Tokyo (JP)

(72) Inventors: Takeshi TAMURA, Koshi City, Kumamoto (JP); Munehisa KODAMA, Kikuchi-gun, Kumamoto (JP); Tomohiro KANEKO, Kikuchi-gun, Kumamoto (JP)

(21) Appl. No.: 18/254,608

(22) PCT Filed: Nov. 15, 2021
(86) PCT No.: PCT/JP2021/041879

§ 371 Date: May 26, 2023

(30) Foreign Application Priority Data
Nov. 27, 2020 (JP) 2020-196956

(51) Int. Cl. B24B 49/02; B24B 7/04

(52) U.S. Cl. CPC B24B 49/02; B24B 7/04

(57) ABSTRACT

A substrate processing system configured to process a combined substrate in which a first substrate and a second substrate are bonded to each other includes a processing apparatus configured to grind the first substrate; a first thickness measuring apparatus configured to measure a thickness of the first substrate before being ground by the processing apparatus and a total thickness of the combined substrate including the first substrate; and a second thickness measuring apparatus configured to measure the thickness of the first substrate after being ground by the processing apparatus.

### TECHNICAL FIELD

The various aspects and embodiments described herein pertain generally to a substrate processing system and a substrate processing method.

### BACKGROUND

Patent Document 1 discloses a grinding apparatus configured to adjust a thickness of a wafer by adjusting an inclination angle of a chuck table. This grinding apparatus is equipped with, near a second grinding position, a finishing thickness measuring apparatus configured to measure only the thickness of the wafer after being subjected to second grinding at multiple points in a radial direction of the wafer. In this grinding apparatus, a thickness distribution of the wafer in the radial direction is investigated from the thicknesses of the wafer measured by the finishing thickness measuring apparatus. Then, based on the investigated thickness distribution of the wafer in the radial direction, the chuck table is tilted by an inclination angle adjusting mechanism to adjust the angle of the wafer with respect to a whetstone so that the thickness of the wafer after being subjected to the second grinding is adjusted.

### PRIOR ART DOCUMENT

Patent Document 1: Japanese Patent Laid-open Publication No. 2008-264913

### DISCLOSURE OF THE INVENTION

### Problems to be Solved by the Invention

Exemplary embodiments provide a technique capable of improving throughput of a substrate processing including grinding of a substrate.

### Means for Solving the Problems

In an exemplary embodiment, a substrate processing system configured to process a combined substrate in which a first substrate and a second substrate are bonded to each other includes a processing apparatus configured to grind the first substrate; a first thickness measuring apparatus configured to measure a thickness of the first substrate before being ground by the processing apparatus and a total thickness of the combined substrate including the first substrate; and a second thickness measuring apparatus configured to measure the thickness of the first substrate after being ground by the processing apparatus.

### Effect of the Invention

According to the exemplary embodiment, it is possible to improve the throughput of the substrate processing including the grinding of the substrate.

### BRIEF DESCRIPTION OF THE DRAWINGS

FIG. 1 is a side view illustrating an example structure of a combined wafer processed in a wafer processing system.

FIG. 2 is a plan view illustrating a configuration example of the wafer processing system.

FIG. 3 is a side view illustrating an internal configuration example of the wafer processing system.

FIG. 4 is an explanatory diagram illustrating a thickness of an upper wafer, a thickness of a lower wafer, and a total thickness of the combined wafer.

FIG. 5 is a side view illustrating a configuration example of individual grinding units.

FIG. 6 is a plan view illustrating a configuration example of a first thickness measuring apparatus.

FIG. 7 is a side view illustrating the configuration example of the first thickness measuring apparatus.

FIG. 8 is a perspective view illustrating the configuration example of the first thickness measuring apparatus.

FIG. 9 is an explanatory diagram illustrating an example of measurement positions of the thickness when viewed from the top.

FIG. 10A to FIG. 10C are plan views illustrating an example of a state in which thickness measurement is performed by a total thickness measurement unit.

FIG. 11A to FIG. 11C are plan views illustrating an example of a state in which thickness measurement is performed by a partial thickness measurement unit.

FIG. 12A to FIG. 12C are explanatory diagrams illustrating an airflow generated in the first thickness measuring apparatus.

FIG. 13 is a plan view illustrating a configuration example of a second thickness measuring apparatus.

FIG. 14 is a side view illustrating the configuration example of the first thickness measuring apparatus.

FIG. 15 is a flowchart illustrating an example of main processes of a wafer processing.

FIG. 16A to FIG. 16F are explanatory diagrams illustrating an example of main processes in the first thickness measuring apparatus.

FIG. 17A to FIG. 17D are explanatory diagrams illustrating an example of main processes in the second thickness measuring apparatus.

FIG. 18 is a plan view illustrating a configuration example of a wafer processing system according to another exemplary embodiment.

### DETAILED DESCRIPTION

Recently, in a semiconductor device manufacturing process, for a combined substrate in which a semiconductor substrate (hereinafter, referred to as “upper wafer”) having devices such as a plurality of electronic circuits formed on a surface thereof and a lower wafer are bonded to each other, the upper wafer is thinned by grinding a rear surface thereof.

The thinning of the upper wafer is performed by bringing a grinding whetstone into contact with the rear surface of the upper wafer in the state that a rear surface of the lower wafer is held by a chuck. However, when performing the grinding of the upper wafer in this way, the degree of flatness (TTV: Total Thickness Variation) of the upper wafer after being ground may be degraded depending on a relative inclination between the grinding whetstone to be brought into contact with the upper wafer and the chuck holding the lower wafer.

In the grinding apparatus disclosed in Patent Document 1 described above, the thickness of the wafer is adjusted to, for example, a uniform thickness by adjusting the inclination angle of the chuck table. Specifically, after the second grinding (finishing grinding) is completed, a thickness distribution of the wafer in the radial direction thereof is investigated by measuring the thickness of the wafer at multiple points in the radial direction. Then, the chuck table is tilted based on this thickness distribution to adjust the inclination of the wafer with respect to the whetstone. Further, in this grinding apparatus, the finishing thickness measuring apparatus is provided near the second grinding position, and it measures the thickness of the wafer while holding the wafer with a chuck. It is attempted to improve production efficiency by shortening the work time for investigating the thickness distribution of the wafer in the radial direction.

However, in the grinding apparatus disclosed in Patent Document 1, the second grinding of the wafer and the thickness measurement of the wafer are performed at the second grinding position. When a tendency after the second grinding is used to adjust the inclination of the chuck table at the time of grinding a next wafer, the work time of the grinding apparatus at the second grinding position becomes long, which results in a decrease of throughput of the overall wafer processing. In this regard, there is still a room for improvement in the conventional wafer processing.

The present disclosure provides a technique capable of improving throughput of a substrate processing including grinding of a substrate. Hereinafter, a wafer processing system as a substrate processing system and a wafer processing method as a substrate processing method according to an exemplary embodiment will be described with reference to the accompanying drawings. In the present specification and the drawings, parts having substantially the same functions and configurations will be assigned same reference numerals, and redundant description will be omitted.

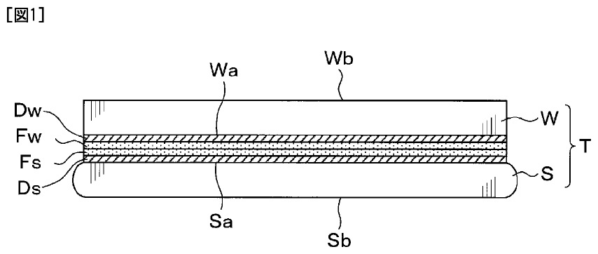

In a wafer processing system 1 to be described later according to the exemplary embodiment, a processing is performed on a combined wafer T as a combined substrate in which an upper wafer Was a first substrate and a lower wafer S as a second substrate are bonded to each other as shown in FIG. 1. In the wafer processing system 1, the upper wafer W is thinned. Hereinafter, in the upper wafer W, a surface to be bonded to the lower wafer W will be referred to as a front surface Wa, and a surface opposite to the front surface Wa will be referred to as a rear surface Wb. Likewise, in the lower wafer W, a surface to be bonded to the upper wafer W will be referred to as a front surface Sa, and a surface opposite to the front surface Sa will be referred to as a rear surface Sb.

The upper wafer W is a semiconductor wafer such as, but not limited to, a silicon wafer, and has, on the front surface Wa thereof, a device layer Dw including a plurality of devices. Further, a surface film Fw is further formed on the device layer Dw, and the device layer Dw is bonded to the lower wafer S with this surface film Fw therebetween. The surface film Fw may be, by way of non-limiting example, an oxide film (a SiO₂ film or a TEOS film), a SiC film, a SiCN film, an adhesive, or the like.

The lower wafer S has the same configuration as that of the upper wafer W, for example, and a device layer Ds and a surface film Fs are formed on the front surface Sa thereof. The lower wafer S does not need to be a device wafer on which the device layer Ds is formed, and it may be, for example, a support wafer supporting the upper wafer W. In this case, the lower wafer S serves as a protection member configured to protect the device layer Dw of the upper wafer W.

In the drawings to be referred to in the following description, in order to avoid complication of illustration, the device layers Dw and Ds and the surface films Fw and Fs may sometimes be omitted.

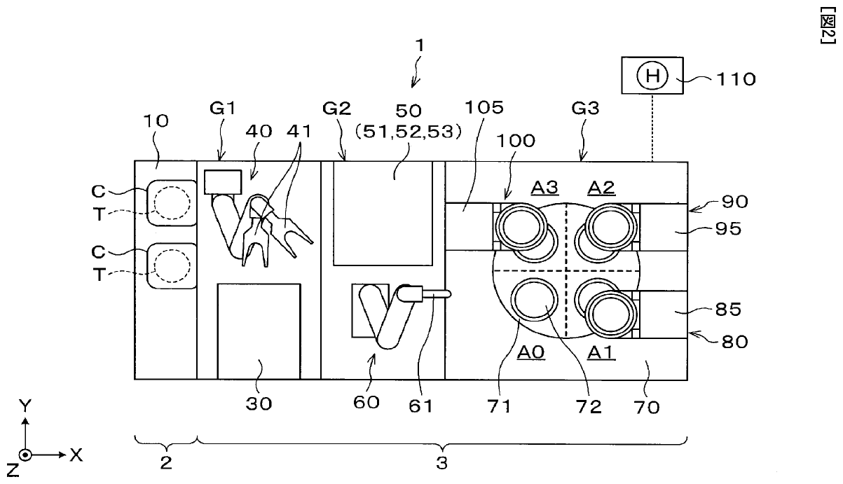

As depicted in FIG. 2 and FIG. 3, the wafer processing system 1 has a structure in which a carry-in/out station 2 and a processing station 3 are connected as one body. In the carry-in/out station 2, a cassette C capable of accommodating a plurality of combined wafers T therein is carried to/from the outside, for example. The processing station 3 is equipped with various kinds of processing apparatuses each configured to perform a required processing on the combined wafer T.

The carry-in/out station 2 as a carry-in/out section is equipped with a cassette placing table 10. In the shown example, a plurality of, for example, two cassettes C can be arranged on the cassette placing table 10 in a row in the Y-axis direction. Further, the number of the cassettes C placed on the cassette placing table 10 is not limited to the example of the present exemplary embodiment but may be selected as required.

The processing station 3 is equipped with, for example, three processing blocks G1 to G3. The first processing block G1, the second processing block G2, and the third processing block G3 are arranged in this order from the negative X-axis side (carry-in/out station 2 side) to the positive X-axis side. The processing blocks G1 to G3 are spatially blocked from each other by partition walls, and the combined wafer T is transferred between the processing blocks G1 to G3 via carry-in/out openings formed in the various kinds of processing apparatuses. Further, a shutter (not shown) is provided at each of the carry-in/out openings formed in the various kinds of processing apparatuses to open or close the corresponding carry-in/out opening.

The first processing block G1 is equipped with etching apparatuses 30 and a wafer transfer device 40. The etching apparatuses 30 are stacked in two levels in a vertical direction, for example. The wafer transfer device 40 is disposed on the positive Y-axis side of the etching apparatus 30. Further, the number and the layout of the etching apparatuses 30 and the wafer transfer device 40 are not limited to the shown example.

The etching apparatus 30 is configured to etch the rear surface Sb of the lower wafer S and the rear surface Wb of the upper wafer W after being grounded. At this time, a cleaning processing such as particle removal and metal component removal are also performed. By way of example, by supplying an etching liquid to the rear surfaces Wb and Sb, the rear surface Wb is wet-etched. For instance, FPM, HF, HNO₃, H₃PO₄, TMAH, Choline, KOH, or the like may be used as the etching liquid.

The wafer transfer device 40 as a first substrate transfer device has, for example, two transfer arms 41 configured to hold and transfer the combined wafer T. Each transfer arm 41 is configured to be movable in a horizontal direction and a vertical direction and pivotable around a horizontal axis and a vertical axis. The wafer transfer device 40 is configured to be capable of transferring the combined wafer T to/from the cassette C of the cassette placing table 10, the etching apparatus 30, a first cleaning apparatus 50 to be described later, a second cleaning apparatus 51 to be described later, a first thickness measuring apparatus 52 to be described later, and a second thickness measuring apparatus 53 to be described later.

In addition, a non-illustrated fan filter unit (FFU) is provided in the first processing block G1. Thus, the cleanliness of the inside of the first processing block G1 is maintained high, and the internal pressure of the processing block G1 is maintained higher than that of the second processing block G2.

The second processing block G2 as a processing section is equipped with the first cleaning apparatus 50, the second cleaning apparatus 51, the first thickness measuring apparatus 52, the second thickness measuring apparatus 53, and a wafer transfer device 60. The first cleaning apparatus 50, the second cleaning apparatus 51, the first thickness measuring apparatus 52, and the second thickness measuring apparatus 53 are stacked in this order from above. The wafer transfer device 60 is disposed on the negative Y-axis side of the first cleaning apparatus 50, the second cleaning apparatus 51, the first thickness measuring apparatus 52, and the second thickness measuring apparatus 53. Here, the number and the layout of the first cleaning apparatus the second cleaning apparatus 51, the first thickness measuring apparatus 52, the second thickness measuring apparatus 53, and the wafer transfer device 60 are not limited to the shown example.

The first cleaning apparatus 50 cleans the rear surface Sb of the lower wafer S and the rear surface Wb of the upper wafer W before being ground in a processing apparatus 70 to be described later. For example, by supplying a cleaning liquid to the rear surface Wb, the first cleaning apparatus 50 cleans the rear surface Wb by spinning, and by bringing a brush into contact with the rear surface Sb, the first cleaning apparatus 50 scrub-cleans the rear surface Sb.

The second cleaning apparatus 51 cleans the rear surface Sb of the lower wafer S and the rear surface Wb of the upper wafer W after being ground in the processing apparatus 70 to be described later. For example, by supplying a cleaning liquid to the rear surface Wb, the second cleaning apparatus 51 cleans the rear surface Wb by spinning, and by bringing a brush into contact with the rear surface Sb, the second cleaning apparatus 51 scrub-cleans the rear surface Sb, in the same manner as in the first cleaning apparatus 50.

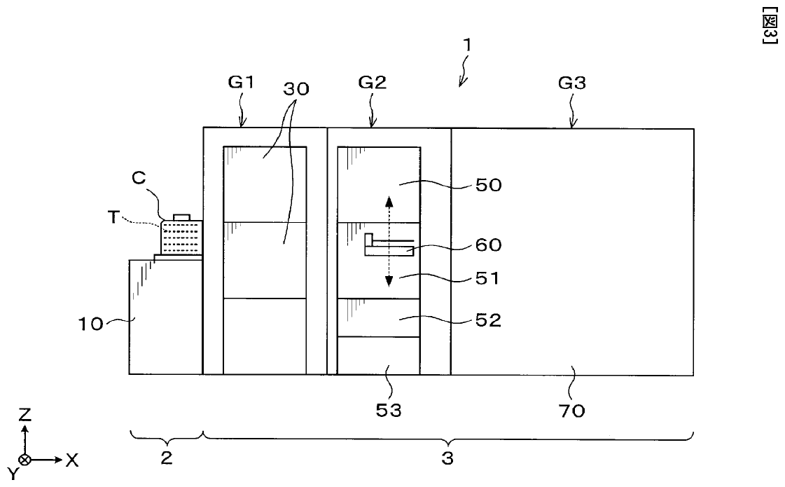

The first thickness measuring apparatus 52 measures a thickness Hw (see FIG. 4) of the upper wafer W before being ground in the processing apparatus 70 to be described later, and a total thickness Ht (see FIG. 4) of the combined wafer T including the upper wafer W. Further, the first thickness measuring apparatus 52 adjusts the direction and the position of the combined wafer T before being ground in a horizontal direction. A detailed configuration of the first thickness measuring apparatus 52 and a detailed method of measuring the thicknesses will be described later.

The second thickness measuring apparatus 53 measures the thickness Hw (see FIG. 4) of the upper wafer W after being ground in the processing apparatus 70 to be described later. Further, the second thickness measuring apparatus 53 adjusts the direction and the position of the combined wafer T after being ground in the horizontal direction. A detailed configuration of the second thickness measuring apparatus 53 and a detailed method of measuring the thickness will be described later.

The wafer transfer device 60 as a second substrate transfer device has, for example, two transfer arms 61 each of which is configured to transfer the combined wafer T by attracting and holding the combined wafer T with an attracting/holding surface (not shown) thereof. Each transfer arm 61 is configured to be movable in a horizontal direction and a vertical direction and pivotable around a horizontal axis and a vertical axis. The wafer transfer device 60 is configured to be capable of transferring the combined wafer T to/from the second cleaning apparatus 51, the first thickness measuring apparatus 52, and the processing apparatus 70 to be described later.

In the present exemplary embodiment, although the following description will be provided for an example case where the combined wafer T is not transferred to the first cleaning apparatus 50 and the second thickness measuring apparatus 53 by the wafer transfer device 60 based on processes of a wafer processing to be described later, there may be adopted a configuration in which the combined wafer T is transferred to the first cleaning apparatus 50 and the second thickness measuring apparatus 53 depending on the processes of the wafer processing.

The single processing apparatus 70 is provided in the third processing block G3 as a machining section. Here, however, the number and the layout of processing apparatus 70 are not limited to the shown example.

The processing apparatus 70 has a rotary table 71. Provided on the rotary table 71 are four chucks 72 each serving as a third substrate holder configured to attract and hold the combined wafer T. For example, a porous chuck is used as the chuck 72, and it attracts and holds the rear surface Sb of the lower wafer S in the combined wafer T. A surface of the chuck 72, that is, a holding surface for the combined wafer T has a protruding shape with a central portion protruding higher than an end portion thereof, when viewed from the side. In addition, since the protrusion of this central portion is minute, the protruding shape of the chuck 72 is omitted in the illustration of the following description.

As illustrated in FIG. 5, the chuck 72 is held by a chuck base 73. The chuck base 73 is provided with an inclination adjusting device 74 configured to adjust relative inclinations between the chuck 72 and grinding wheels belonging to individual grinding units (a rough grinding unit 80, an intermediate grinding unit 90, and a finishing grinding unit 100) to be described later. The inclination adjusting device 74 has a fixed shaft 75 provided on a bottom surface of the chuck base 73 and a plurality of, for example, two elevating shafts 76. Each of the elevating shafts 76 is configured to be extensible/contractible, and moves the chuck base 73 up and down. The inclination adjusting device 74 is capable of allowing the chuck 72 and the chuck base 73 to be inclined by raising or lowering one end of an outer periphery of the chuck base 73 in a vertical direction with the elevating shaft 76 with respect to the other end thereof (a position corresponding to the fixed shaft 75). Thus, it is possible to adjust the relative inclination between the surface of the chuck 72 and surfaces of the grinding wheels of the individual grinding units 80, 90, and 100 located at the processing positions A1 to A3, respectively.

Furthermore, the configuration of the inclination adjusting device 74 is not limited to the above-described example, and any of various other configurations may be selected as long as the relative angle (parallelism) of the surface of the chuck 72 with respect to the surface of the grinding wheel can be adjusted.

As shown in FIG. 2, the four chucks 72 can be moved to a delivery position A0 and the processing positions A1 to A3 as the rotary table 71 is rotated. Further, each of the four chucks 72 is configured to be rotatable around a vertical axis by a rotating mechanism (not shown).

At the delivery position A0, a delivery of the combined wafer T by the wafer transfer device 60 is performed. The rough grinding unit 80 is disposed at the processing position A1 to roughly grind the upper wafer W. The intermediate grinding unit 90 is disposed at the processing position A2 to grind the upper wafer W to an intermediate level. The finishing grinding unit 100 is disposed at the processing position A3 to finely grind the upper wafer W.

As depicted in FIG. 5, the rough grinding unit 80 includes a rough grinding wheel 81 having an annular rough grinding whetstone on a bottom surface thereof, a mount 82 supporting the rough grinding wheel 81, and a spindle 83 configured to rotate the rough grinding wheel 81 via the mount 82, and a driver 84 having, for example a motor (not shown) embedded therein. Further, the rough grinding unit 80 is configured to be movable in a vertical direction along a supporting column 85 shown in FIG. 2.

The intermediate grinding unit 90 has the same configuration as the rough grinding unit 80. That is, the intermediate grinding unit 90 has an intermediate grinding wheel 91 provided with an annular intermediate grinding whetstone, a mount 92, a spindle 93, a driver 94, and a supporting column 95. The particle size of abrasive grains of the intermediate grinding whetstone is smaller than the particle size of abrasive grains of the rough grinding whetstone.

The finishing grinding unit 100 has the same configuration as the rough grinding unit 80 and the intermediate grinding unit 90. That is, the finishing grinding unit 100 has a finishing grinding wheel 101 provided with an annular finishing grinding whetstone, a mount 102, a spindle 103, a driver 104, and a supporting column 105. The particle size of abrasive grains of the finishing grinding whetstone is smaller than the particle size of the abrasive grains of the intermediate grinding whetstone.

In addition, a non-illustrated exhaust unit is provided in the third processing block G3. Thus, particles or the like generated by the grinding processing in the processing apparatus 70 are exhausted, and the internal pressure of the third processing block G3 is maintained lower than the internal pressure of the second processing block G2. That is, in the wafer processing system 1, the internal pressures of the first processing block G1, the second processing block G2, and the third processing block G3 are controlled to be higher in this order.

As shown in FIG. 2, the above-described wafer processing system 1 has a control device 110. The control device 110 is, for example, a computer equipped with a CPU, a memory, and the like, and has a program storage (not shown). The program storage stores therein a program for controlling the wafer processing in the wafer processing system 1. Further, the program may be recorded in a computer-readable recording medium H and installed from this recording medium H to the control device 110.

Now, the detailed configuration of the aforementioned first thickness measuring apparatus 52 will be explained.

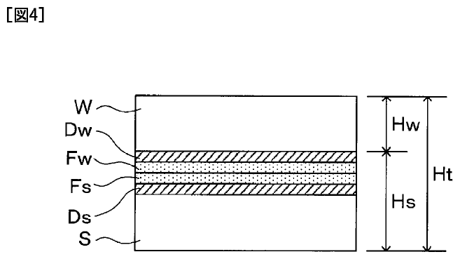

As depicted in FIG. 6 and FIG. 7, the first thickness measuring apparatus 52 has a chuck 300 as a first substrate holder configured to hold the combined wafer T. The chuck 300 is configured to attract and hold a central portion of the rear surface Sb of the lower wafer S in the combined wafer T. Further, the diameter of the chuck 300 is, for example, equal to or less than a half of the diameter of the combined wafer T.

The chuck 300 is provided with a notch 301 extending from a center of the chuck 300 to an outer end thereof in a radial direction (Y-axis direction). The notch 301 is formed so as to allow a lower sensor 332 of the total thickness measuring apparatus 330 to be described later to be advanced thereinto and retreated therefrom.

The chuck 300 is configured to be rotatable about a vertical axis and movable in a horizontal direction. Provided below the chuck 300 is a rotating mechanism 310 configured to rotate the chuck 300. A driving unit (not shown) such as, but not limited to, a motor is incorporated in the rotating mechanism 310. The rotating mechanism 310 is supported by a supporting member 311. The supporting member 311 is mounted to a rail 312 extending in a horizontal direction (Y-axis direction). The supporting member 311 is configured to be movable along the rail 312 by a moving mechanism 313 provided on the rail 312. A driving unit (not shown) such as, but not limited to, a motor is incorporated in the moving mechanism 313. Further, in the present exemplary embodiment, the rotating mechanism 310 and the moving mechanism 313 that drive the chuck 300 constitute a “first driving unit” according to the present disclosure.

A position detection unit 320 as a first position detector is provided on the lateral side (negative X-axis side) of the chuck 300. The position detection unit 320 is configured to detect the position of the combined wafer T before being ground in the horizontal direction. The position detection unit 320 has a sensor configured to radiate light to an outer periphery of the lower wafer S held by the chuck 300 and receive the light. Alternatively, the position detection unit 320 may have a sensor configured to image the outer periphery of the lower wafer S. While rotating the combined wafer T held by the chuck 300, the position detection unit 320 detects the position of the notch of the lower wafer S, and also detects the position (eccentric amount) of the center of the combined wafer T (upper wafer W). The detection result of the position detection unit 320 is outputted to the control device 110. Then, based on this detection result, the direction of the combined wafer T in the horizontal direction is adjusted (0 alignment), and the position of the combined wafer T in the horizontal direction is adjusted (X-Y alignment). In addition, although the position of the notch of the lower wafer S is detected in the present exemplary embodiment, the present disclosure is not limited thereto. By way of example, a position of an orientation flat of the lower wafer S may be detected to adjust the direction and the position of the combined wafer T in the horizontal direction.

Above and below the chuck 300, a total thickness measurement unit 330 is provided. The total thickness measurement unit 330 is configured to measure the total thickness Ht of the combined wafer T shown in FIG. 4. Further, the total thickness Ht of the combined wafer T measured by the total thickness measurement unit 330 is outputted to the control device 110.

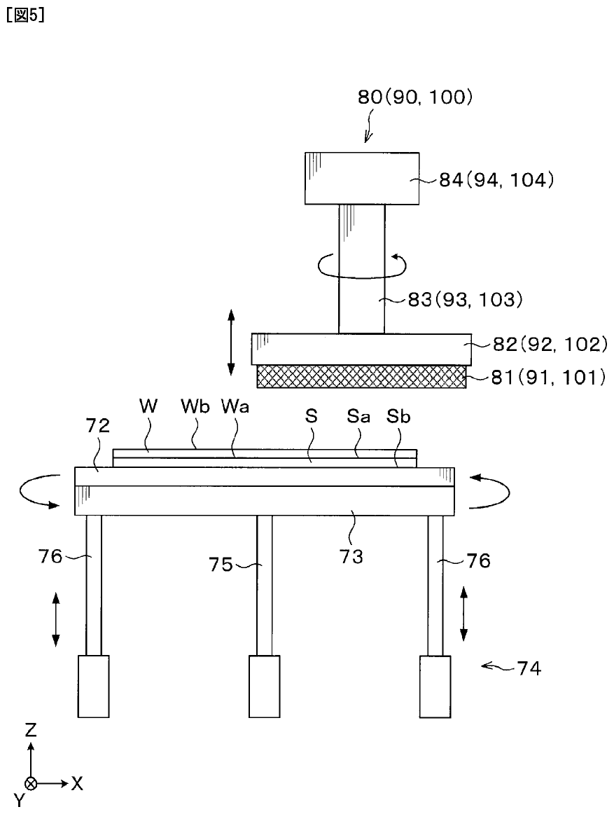

As shown in FIG. 6 to FIG. 8, the total thickness measurement unit 330 has an upper sensor 331, a lower sensor 332, and a non-illustrated calculation unit. The upper sensor 331 is disposed above the combined wafer T held by the chuck 300, and measures a distance from the upper sensor 331 to the rear surface Wb of the upper wafer W. The lower sensor 332 is disposed below the combined wafer T held by the chuck 300, and measures a distance from the lower sensor 332 to the rear surface Sb of the lower wafer S. Further, the upper sensor 331 and the lower sensor 332 are disposed to face each other on the same coordinate axis, and a measurement point of the upper sensor 331 and a measurement point of the lower sensor 332 are one and the same position when viewed from the top. Furthermore, in the total thickness measurement unit 330, the total thickness Ht of the combined wafer T is calculated by the calculation unit based on the distance between the upper sensor 331 and the rear surface Wb of the upper wafer W and the distance between the lower sensor 332 and the rear surface Sb of the lower wafer S. In addition, each of the upper sensor 331 and the lower sensor 332 may be implemented by a commonly known sensor capable of measuring a distance. For example, a confocal sensor may be used. In addition, the non-illustrated calculation unit may be provided inside or outside the first thickness measuring apparatus 52.

The upper sensor 331 and the lower sensor 332 are moved relative to the chuck 300 as the chuck 300 is moved in the horizontal direction. Further, the lower sensor 332 is configured to be capable of advancing into and retreating from the notch 301. That is, as the chuck 300 is moved in the horizontal direction, the lower sensor 332 advances into or retreats from the notch 301. The total thickness measurement unit 330 is capable of measuring the total thickness Ht of the combined wafer T at multiple points.

Moreover, the upper sensor 331 and the lower sensor 332 are disposed at positions where the lower sensor 332 and the notch 301 do not interfere with each other when the combined wafer T is rotated in the above-described detection of the position of the combined wafer T in the horizontal direction by the position detection unit 320, that is, they are disposed on the positive Y-axis side of the position detection unit 320.

Further provided above the chuck 300 is a partial thickness measurement unit 340 as a first measurement unit. The partial thickness measurement unit 340 is configured to measure the thickness Hw of the upper wafer W shown in FIG. 4. The partial thickness measurement unit 340 measures the thickness of the upper wafer W without coming into contact with the upper wafer W. Further, the thickness Hw of the upper wafer W measured by the partial thickness measurement unit 340 is outputted to the control device 110. In the control device 110, a thickness Hs of a portion of the combined wafer T other than the upper wafer W is calculated by subtracting the thickness Hw of the upper wafer W from the total thickness Ht of the combined wafer T measured by the total thickness measurement unit 330. This thickness Hs includes the thickness of the lower wafer S, the thicknesses of the device layers Dw and Ds, and the thicknesses of the surface films Fw and Fs, which will sometimes be simply referred to the thickness Hs of the lower wafer S.

The calculated thickness Hs of the lower wafer S is outputted to the control device 110. Then, based on the thickness Hs of the lower wafer S, the relative angle (parallelism) of the surface of the chuck 72 with respect to the surface of the grinding wheel in the processing apparatus 70 is adjusted.

As shown in FIG. 6 to FIG. 8, the partial thickness measurement unit 340 has a sensor 341 and a non-illustrated calculation unit. The sensor 341 is configured to radiate light to the upper wafer W and receive reflection light reflected from the front surface Wa of the upper wafer W and reflection light reflected from the rear surface Wb of the upper wafer W. Then, in the partial thickness measurement unit 340, the thickness Hw of the upper wafer W is measured by the calculation unit based on these reflection lights. Further, the sensor 341 is disposed at the same position as the above-described position detection unit 320 in the Y-axis direction. Here, a commonly known sensor capable of measuring a thickness may be used for the sensor 341. For example, a spectral interference type sensor may be used. Furthermore, the non-illustrated calculation unit may be provided inside or outside the first thickness measuring apparatus 52.

The sensor 341 is moved relative to the chuck 300 as the chuck 300 is moved in the horizontal direction. The partial thickness measurement unit 340 is capable of measuring the thickness Hw of the upper wafer W at multiple points.

The total thickness measurement unit 330 and the partial thickness measurement unit 340 respectively measure the total thickness Ht of the combined wafer T and the thickness Hw of the upper wafer W at the same measurement point when viewed from the top. That is, as shown in FIG. 9, the total thickness measurement unit 330 and the partial thickness measurement unit 340 measure the total thickness Ht of the combined wafer T and the thickness Hw of the upper wafer W, respectively, at three points in the radial direction. A measurement point P1 is the center of the upper wafer W. A measurement point P2 is a middle portion of the upper wafer W and is a position corresponding to R/2 from the center of the upper wafer W when the radius of the upper wafer W is R. A measurement point P3 is the outer periphery of the upper wafer W.

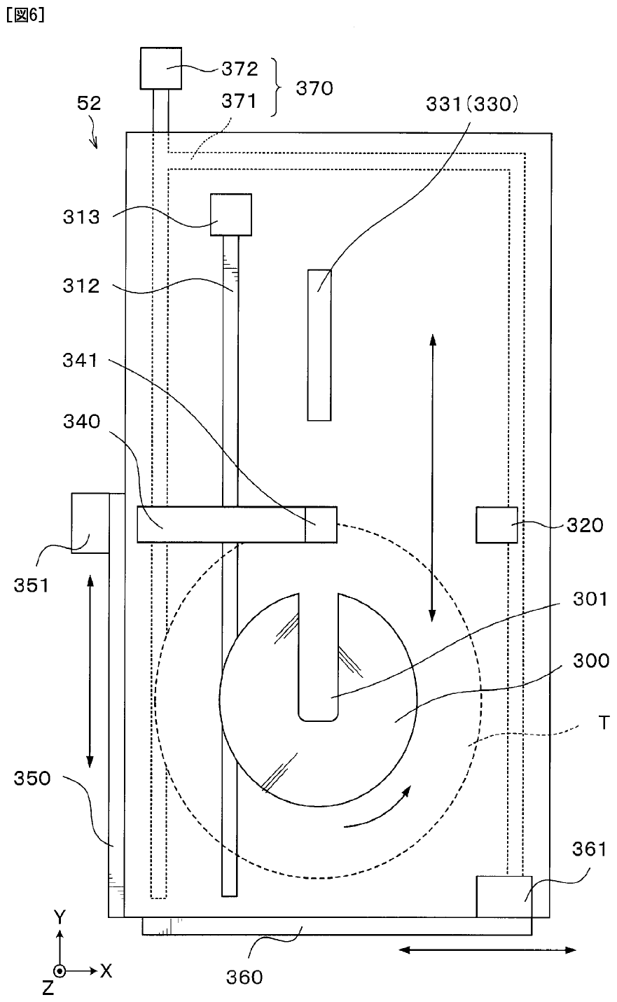

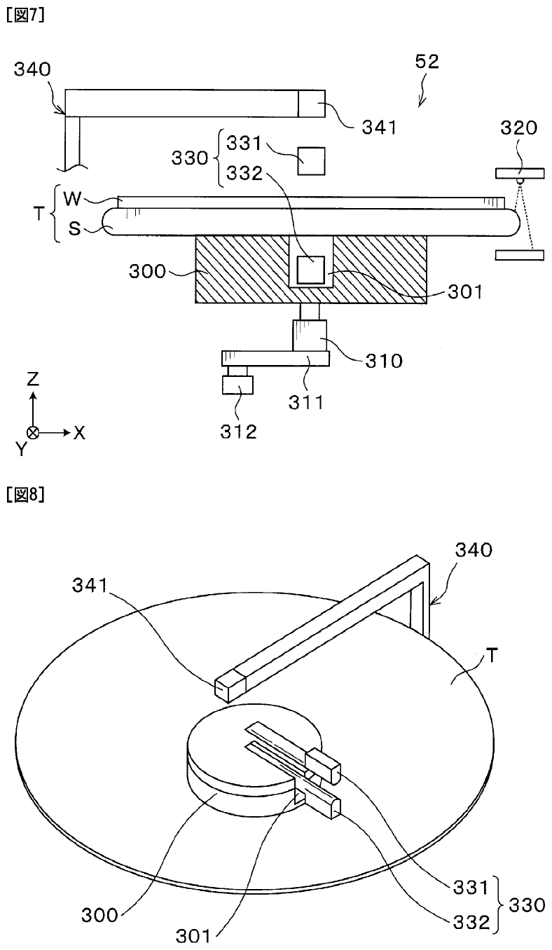

As depicted in FIG. 10A, in the measurement of the total thickness Ht at the measurement point P1 by the total thickness measurement unit 330, the total thickness Ht of the combined wafer T is measured in the state that the rotation of the chuck 300 (combined wafer T) is stopped. At this time, the lower sensor 332 is located in the notch 301. Therefore, in order to avoid the interference between the lower sensor 332 and the chuck 300, the chuck 300 is not rotated.

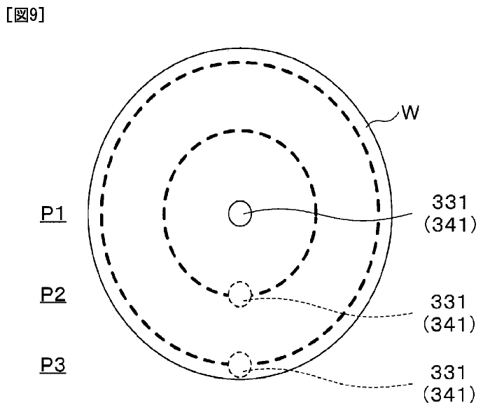

Meanwhile, as shown in FIG. 11A, in the measurement of the thickness Hw of the upper wafer W at the measurement point P1 by the partial thickness measurement unit 340, interference between the sensor 341 and the chuck 300 does not occur. Thus, the chuck 300 (combined wafer T) may be rotated, or the rotation thereof may be stopped.

As illustrated in FIG. 10B, in the measurement of the total thickness Ht at the measurement point P2 by the total thickness measurement unit 330, the total thickness Ht of the combined wafer T is measured at multiple points in a circumferential direction while rotating the chuck 300. At this time, since the diameter of the chuck 300 is less than the half of the diameter of the combined wafer T, the lower sensor 332 is retreated from the notch 301. Thus, even if the chuck 300 is rotated, the lower sensor 332 and the chuck 300 do not interfere with each other.

Further, as shown in FIG. 11B, in the measurement of the thickness Hw of the upper wafer W at the measurement point P2 by the partial thickness measurement unit 340 as well, the thickness Hw of the upper wafer W is measured at multiple points in the circumferential direction while rotating the chuck 300.

Then, at the measurement point P2, a moving average value of the measured thicknesses of the multiple points in the circumferential direction is calculated, and this moving average value is set as the total thickness Ht of the combined wafer T or the thickness Hw of the upper wafer W at the measurement point P2. Alternatively, a moving median value of the thicknesses of the multiple points in the circumferential direction may be set as the measurement thickness at the measurement point P2.

As shown in FIG. 10C and FIG. 11C, at the measurement point P3 as well, the total thickness Ht of the combined wafer T and the thickness Hw of the upper wafer W are measured in the same way as measured at the measurement point P2.

In the present exemplary embodiment, the moving average value or the moving median value of the multiple points in the circumferential direction at the measurement point P2 (P3) is used as the measurement thickness at the measurement point P2 (P3). However, the thickness may be measured at designated coordinates, for example. By way of example, at the measurement point P2 (P3), the total thickness Ht of the combined wafer T or the thickness Hw of the upper wafer W is measured in the state that the rotation of the combined wafer T is stopped. Accordingly, at the measurement point P2 (P3), the total thickness Ht or the thickness Hw of the upper wafer W at one point in the circumferential direction is measured. Then, this thickness measured at these designated coordinates may be used as the thickness at the measurement point P2 (P3) as a representative point.

Further, in the present exemplary embodiment, the measurement result of the thickness Hw of the upper wafer W is used to adjust the parallelism between the surface of the chuck 72 and the surface of the finishing grinding wheel 101 as will be described later. However, the use thereof is not limited thereto. By way of example, in order to investigate the tendency of the thickness Hw of the upper wafer W, the thickness Hw of the upper wafer W may be measured at a designated measurement point.

In addition, in the first thickness measuring apparatus 52 of the present exemplary embodiment, the chuck 300 is moved in the horizontal direction (Y-axis direction), whereas the upper sensor 331 and the lower sensor 332 of the total thickness measurement unit 330, and the sensor 341 of the partial thickness measurement unit 340 are fixed. However, the chuck 300 and the total thickness measurement unit 330 or the partial thickness measurement unit 340 just need to be moved relatively in the horizontal direction. For example, the chuck 300 may be fixed, whereas the upper sensor 331 and the lower sensor 332, or the sensor 341 may be moved in the horizontal direction. Alternatively, the chuck 300 may be moved in the horizontal direction, and the upper sensor 331 and the lower sensor 332, or the sensor 341 may also be moved in the horizontal direction.

As depicted in FIG. 6, a first shutter 350 is provided on a sidewall surface of the first thickness measuring apparatus 52 on the negative X-axis side. The first shutter 350 is configured to be driven by a driving mechanism 351 to open or close a first transfer opening. As this first shutter 350 is opened, the inside of the first thickness measuring apparatus 52 and the inside of the first processing block G1 are allowed to communicate with each other, and the combined wafer T is carried in or out by the wafer transfer device 40.

Further, a second shutter 360 is provided on a sidewall surface of the first thickness measuring apparatus 52 on the negative Y-axis side. The second shutter 360 is configured to be driven by a driving mechanism 361 to open or close a second transfer opening. As this second shutter 360 is opened, the inside of the first thickness measuring apparatus 52 and the inside of the second processing block G2 are allowed to communicate with each other, and the combined wafer T is carried in or out by the wafer transfer device 60.

An exhaust unit 370 is connected to a lower portion of the first thickness measuring apparatus 52. The exhaust unit 370 has an exhaust path 371 provided below a driving component such as the rail 312; and an exhaust mechanism 372 such as a vacuum pump connected to the exhaust path 371. Through the operation of the exhaust mechanism 372, the exhaust unit 370 exhausts particles or the like generated as a result of driving such as the rotation and the movement of the chuck 300 to the outside of the first thickness measuring apparatus 52.

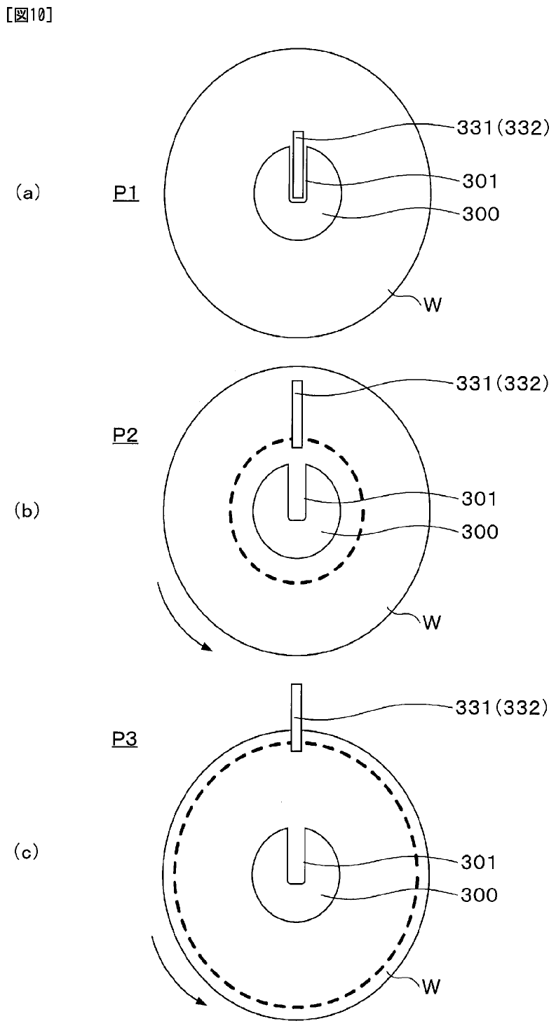

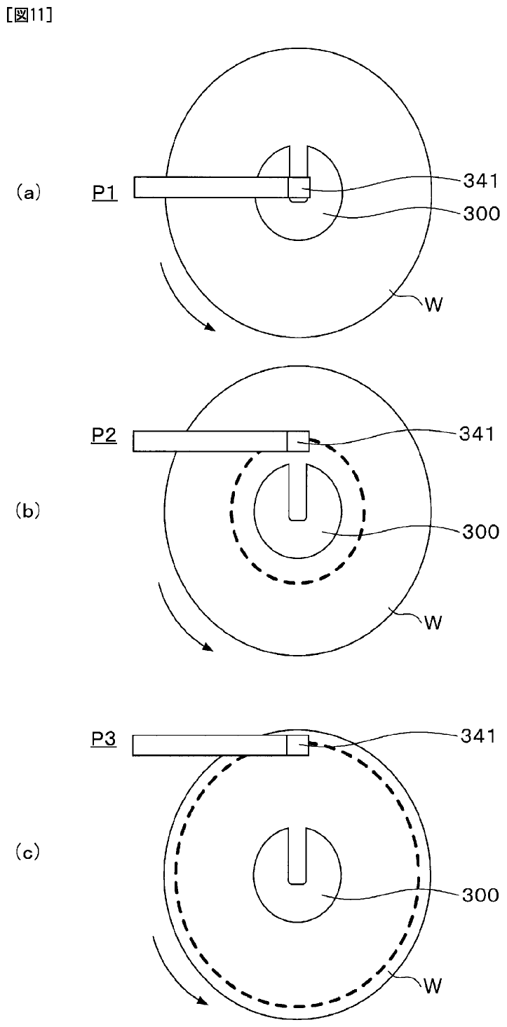

Moreover, the exhaust unit 370 is configured to evacuate (decompress) a processing space of the first thickness measuring apparatus 52. The internal pressure of the first thickness measuring apparatus 52 is controlled to be maintained at a pressure lower than the internal pressure of the first processing block G1 and higher than the internal pressure of the second processing block G2. In other words, in the first thickness measuring apparatus 52, an airflow flows in from the first processing block G1 when the first shutter 350 is opened, whereas the airflow flows out to the second processing block G2 when the second shutter 360 is opened. Accordingly, as shown in FIG. 12A to FIG. 12C, an inflow of particles or the like generated by the grinding processing in the processing apparatus 70 into the first thickness measuring apparatus 52 is suppressed, and an outflow of the particles or the like to the first processing block G1 (cassette C) as a clean space is suppressed.

Specifically, as shown in FIG. 12A, for example, when the first shutter 350 and the second shutter 360 are closed, an outflow of the airflow from the first thickness measuring apparatus 52 does not occur, and the airflow is exhausted only from the exhaust unit 370. Further, even when the first shutter 350 is closed in this way, a minute amount of airflow is introduced from the first processing block G1 as the clean space through a minute gap formed on the first shutter 350 side, as shown in FIG. 12A.

Further, as shown in FIG. 12B, when the first shutter 350 is opened, the airflow is exhausted only from the exhaust unit 370.

In addition, as shown in FIG. 12C, when the second shutter 360 is opened, neither an inflow of the airflow from the second shutter 360 to the first thickness measuring apparatus 52 nor an outflow of the airflow from the first shutter 350 to the outside of the first thickness measuring apparatus 52 occur.

As described above, in the first thickness measuring apparatus 52, the airflow is introduced only from the first shutter 350 (first processing block G1) side, and no airflow from the second shutter 360 (processing apparatus 70) side is introduced. That is, an inflow of the particles or the like from the processing apparatus 70 is suppressed.

Moreover, the airflow is flown out from the first thickness measuring apparatus 52 only from the second shutter 360 (processing apparatus 70) side and the exhaust unit 370, and no airflow is flown out from the first shutter 350 (first processing block G1) side. That is, the particles or the like is suppressed from being flown out to the first processing block G1 as the clean space.

In addition, as shown in FIG. 12A to FIG. 12C, in the first thickness measuring apparatus 52, the timing when the first shutter 350 and the second shutter 360 are opened simultaneously is not created. Accordingly, the outflow of the particles or the like from the processing apparatus 70 to the first processing block G1 is further suppressed.

Now, a detailed configuration of the second thickness measuring apparatus 53 will be described. In the second thickness measuring apparatus 53, parts having substantially the same functions and configurations as those of the first thickness measuring apparatus 52 will be assigned same reference numerals, and redundant description thereof will be omitted.

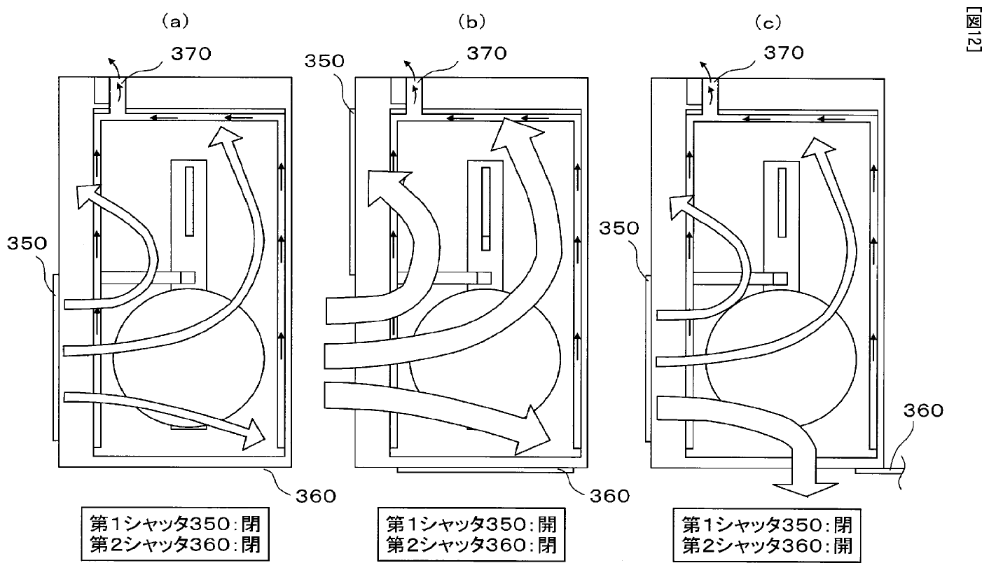

As depicted in FIG. 13 and FIG. 14, the second thickness measuring apparatus 53 has a chuck 400 as a second substrate holder configured to hold the combined wafer T. The chuck 400 is configured to attract and hold the central portion of the rear surface Sb of the lower wafer S in the combined wafer T. In addition, the diameter of the chuck 400 may be, for example, larger than the diameter of the chuck 300 of the first thickness measuring apparatus 52 and equal to or larger than the half of the diameter of the combined wafer T.

The second thickness measuring apparatus 53 performs measurement of the thickness Hw of the upper wafer W after being ground, in other words, the thickness Hw smaller than the thickness Hw of the upper wafer W before being ground that is measured by the first thickness measuring apparatus 52. Therefore, by attracting and holding the combined wafer T with the chuck 400 having the diameter larger than that of the chuck 300 as stated above, the combined wafer T thinned by the grinding is suppressed from being bent.

The chuck 400 is configured to be rotatable around a vertical axis by the rotating mechanism 310 and, also, to be movable in the horizontal direction along the rail 312. Further, a position detection unit 320 as a second position detector is provided on the lateral side (negative X-axis side) of the chuck 400 to adjust the direction and the position of the combined wafer T after being ground in the horizontal direction and, also, to detect the position (eccentric amount) of the center of the upper wafer W. Further, in the present exemplary embodiment, the rotating mechanism 310 and the moving mechanism 313 that drive the chuck 400 constitute a “second driving unit” according to the present disclosure.

Above the chuck 400, there is provided a partial thickness measurement unit 440 as a second measurement unit that measures the thickness Hw of the upper wafer W after being ground. The partial thickness measurement unit 440 measures the thickness of the upper wafer W without coming into contact with the upper wafer W. Further, as described above, the second thickness measuring apparatus 53 performs the measurement of the thickness Hw of the upper wafer W after being ground, in other words, the thickness Hw smaller than the thickness Hw of the upper wafer W before being ground that is measured by the first thickness measuring apparatus 52. For this reason, the partial thickness measurement unit 440 is provided with a sensor 441 capable of measuring a thickness smaller than the thickness measured by the partial thickness measurement unit 340 of the first thickness measuring apparatus 52.

Furthermore, the thickness Hw of the upper wafer W measured by the partial thickness measurement unit 440 is outputted to the control device 110. Then, based on the thickness Hw of the upper wafer W, the relative angle (parallelism) of surface of the chuck 72 with respect to the surface of the grinding wheel for a grinding processing of a combined wafer T to be processed next in the wafer processing system 1 is adjusted.

The partial thickness measurement unit 440 measures the thickness Hw of the upper wafer W at the same measurement point as the total thickness measurement unit 330 and the partial thickness measurement unit 340 in the first thickness measuring apparatus 52, when viewed from the top. That is, the partial thickness measurement unit 440 measures the thickness Hw of the upper wafer W at the three points in the radial direction shown in FIG. 9, for example. Here, the method of measuring the thickness Hw of the upper wafer W by the partial thickness measurement unit 440 is the same as the method measuring the thickness Hw of the upper wafer W by the partial thickness measurement unit 340 shown in FIG. 11A to FIG. 11C.

Further, in the second thickness measuring apparatus 53, a thickness measured at designated coordinates may be used as a thickness at the measurement point P2 (P3) as a representative point instead of a moving average value or a moving median value of thicknesses of multiple points of the upper wafer W in the circumferential direction, the same as in the first thickness measuring apparatus 52.

Further, in the present exemplary embodiment, the measurement result of the thickness Hw of the upper wafer W is used to adjust the relative angle of the surface of the chuck 72 with respect to the surface of the grinding wheel in the grinding processing of the combined wafer T to be processed next. However, the use of the measurement result of the thickness Hw is not limited thereto. By way of example, in order to investigate the tendency of the thickness Hw of the upper wafer W, the thickness Hw of the upper wafer W may be measured at a designated measurement point.

In addition, as stated above, the measurement of the total thickness Ht of the combined wafer T is not performed in the second thickness measuring apparatus 53. For this reason, the second thickness measuring apparatus 53 is not provided with the total thickness measurement unit 330, unlike the first thickness measuring apparatus 52. Furthermore, since the second thickness measuring apparatus 53 is not equipped with the total thickness measurement unit 330 (lower sensor 332) as stated above, the chuck 400 does not have a notch for allowing the lower sensor 332 to be advanced thereinto.

As shown in FIG. 13, a first shutter 350 is provided on a side wall surface of the second thickness measuring apparatus 53 on the negative X-axis side. The first shutter 350 is configured to be driven by the driving mechanism 351 to open or close a first transfer opening. As the first shutter 350 is opened, the inside of the second thickness measuring apparatus 53 and the inside of the first processing block G1 are allowed to communicate with each other, and the combined wafer T is carried in or out by the wafer transfer device 40.

In addition, as described above, in the second thickness measuring apparatus 53, a carry-in/out of the combined wafer T by the wafer transfer device 60 of the second processing block G2 is not performed, and the carry-in/out of the combined wafer T is performed only by the wafer transfer device 40 of the first processing block G1. For this reason, the second thickness measuring apparatus 53 is not provided with a second transfer opening on the second processing block G2 side, that is, it is not provided with the second shutter 360. As described above, in the second thickness measuring apparatus 53, the thickness Hw of the combined wafer T (upper wafer W) after being ground is measured. By omitting the second shutter 360 on the second processing block G2 side and performing the carry-in/out of the combined wafer T only by the wafer transfer device 40 as described above, the particles or the like generated by the grinding processing in the processing apparatus 70 are suppressed from being introduced into the second thickness measuring apparatus 53.

In addition, an exhaust unit 370 is provided below the second thickness measuring apparatus 53. With this configuration, particles or the like generated by the rotation of the chuck 400 and the movement of the chuck 400 in the horizontal direction can be exhausted to the outside of the second thickness measuring apparatus 53, and the second thickness measuring apparatus 53 can be decompressed. For example, the internal pressure of the second thickness measuring apparatus 53 is controlled to be maintained at a pressure lower than the internal pressure of the first processing block G1.

The first thickness measuring apparatus 52 and the second thickness measuring apparatus 53 according to the present exemplary embodiment are configured as described above. Now, a wafer processing performed by using the wafer processing system 1 configured as described above will be described. In the present exemplary embodiment, the upper wafer W and the lower wafer S are bonded in a bonding apparatus (not shown) provided outside the wafer processing system 1 to form the combined wafer T in advance.

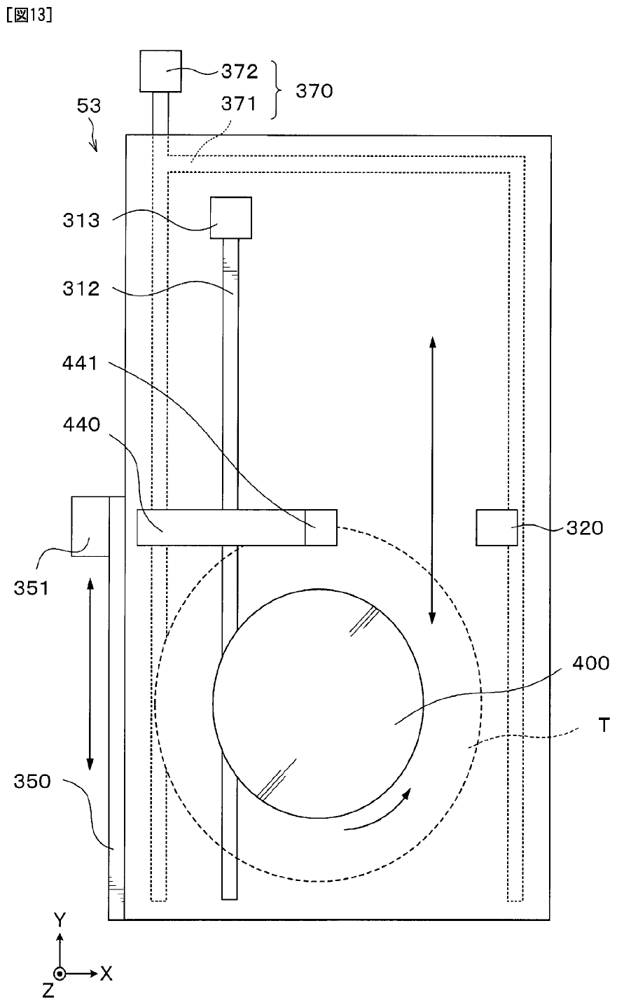

First, the cassette C accommodating therein the plurality of combined wafers T is placed on the cassette placing table 10 of the carry-in/out station 2. Then, the combined wafer T in the cassette C is taken out by the wafer transfer device 40 and transferred to the first cleaning apparatus 50. In the first cleaning apparatus 50, by supplying the cleaning liquid to the rear surface Wb of the upper wafer W while rotating the combined wafer T, the rear surface Wb is cleaned by the spinning. Further, by supplying the cleaning liquid in the state that the cleaning brush (not shown) is brought into contact with the rear surface Sb of the lower wafer S, the rear surface Sb is scrub-cleaned (process E1 in FIG. 15).

Next, the first shutter 350 of the first thickness measuring apparatus 52 is opened, and the combined wafer T is transferred to the first thickness measuring apparatus 52 by the wafer transfer device 40. At this time, since the internal pressure of the first thickness measuring apparatus 52 is controlled to be lower than the internal pressure of the first processing block G1, the first processing block G1 as the clean space is suppressed from being contaminated as a result of opening the first shutter 350. In the first thickness measuring apparatus 52, the combined wafer T is first attracted to and held by the chuck 300 at a carry-in/out position (home position).

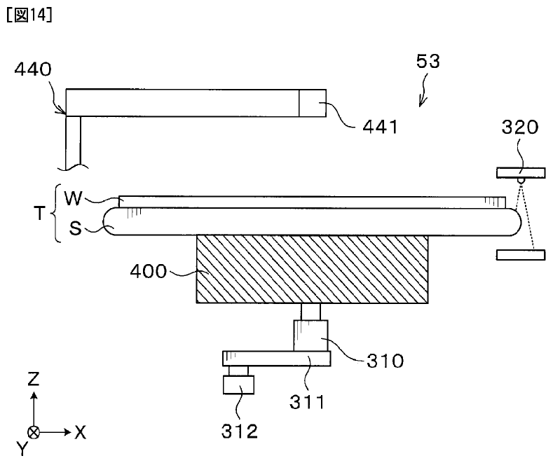

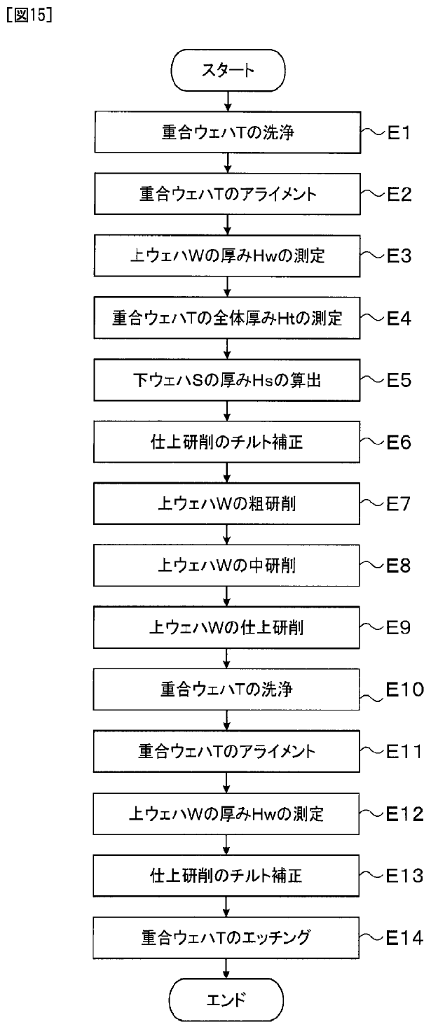

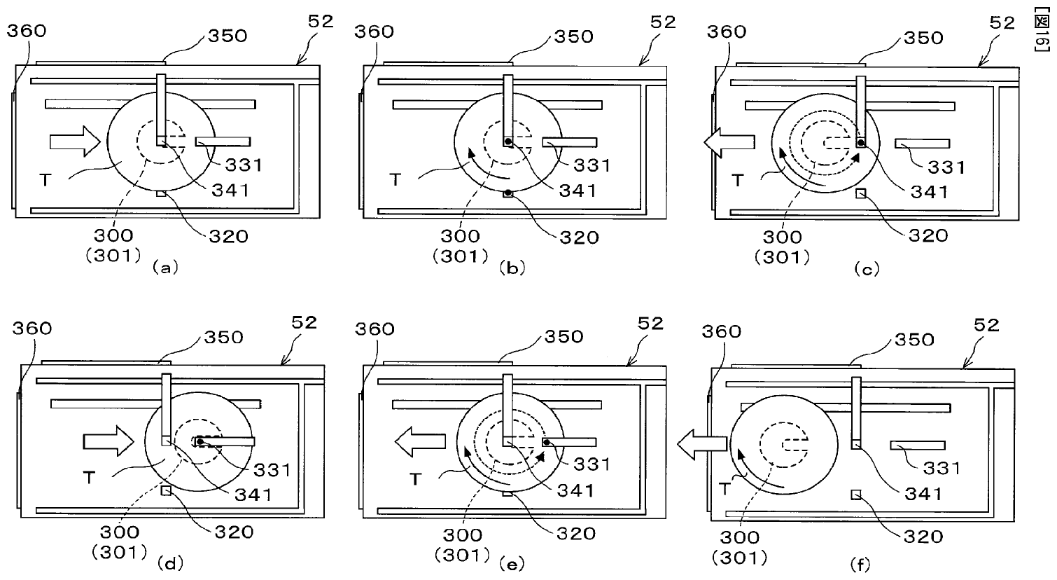

Subsequently, the chuck 300 is moved to an alignment position as shown in FIG. 16A. Then, as illustrated in FIG. 16B, while rotating the combined wafer T, the position of the combined wafer T in the horizontal direction is detected by the position detection unit 320, and the position (eccentric amount) of the center of the upper wafer W is also detected. Based on this detection result, the direction of the combined wafer T in the horizontal direction is adjusted (0 alignment), and the position in the horizontal direction is also adjusted (X-Y alignment) (process E2 in FIG. 15).

Further, at the alignment position, the thickness Hw of the upper wafer W before being ground is measured by the partial thickness measurement unit 340 by the method shown in FIG. 11A to FIG. 11C (process E3 in FIG. 15). That is, the thickness Hw at the center (measurement point P1) of the upper wafer W is first measured. In the measurement of the thickness Hw of the upper wafer W at the measurement point P1, the chuck 300 (combined wafer T) may be rotated or the rotation thereof may be stopped. Further, the measurement of the thickness Hw of the upper wafer W at the measurement point P1 may be performed simultaneously with the detection (process E2) of the position of the combined wafer T in the horizontal direction. The thickness Hw (distribution of the thickness Hw) of the upper wafer W measured in this way is outputted to the control device 110.

Thereafter, as illustrated in FIG. 16C, by sequentially performing the movement of the chuck 300 to the negative Y-axis side and the rotation of the chuck 300, the thickness Hw of the upper wafer W is measured at the multiple points (measurement points P2 and P3) in the radial direction. In the measurement of the thickness Hw of the upper wafer W at the measurement points P2 and P3, the thickness Hw of the upper wafer W is measured at multiple points in the circumferential direction while rotating the chuck 300, and the moving average value or the moving median value of the thicknesses of the upper wafer W obtained at the multiple points in the circumferential direction is calculated.

Then, as depicted in FIG. 16D, the chuck 300 is moved to the total thickness measurement unit 330, and the total thickness Ht of the combined wafer T is measured by the method shown in FIG. 10A to FIG. 10C (process E4 in FIG. 15). That is, the total thickness Ht at the center (measurement point P1) of the combined wafer T is first measured. At the measurement point P1, since the lower sensor 332 is advanced in the notch 301, the total thickness measurement unit 330 measures the total thickness Ht of the combined wafer T in the state that the rotation of the combined wafer T is stopped.

Next, as shown in FIG. 16E, by sequentially performing the movement of the chuck 300 to the positive Y-axis side and the rotation of the chuck 300, the total thickness Ht of the combined wafer T is measured at the multiple points (measurement points P2 and P3) in the radial direction. In the measurement of the total thickness Ht of the combined wafer T at the measurement points P2 and P3, the total thickness Ht of the combined wafer T is measured at multiple points in the circumferential direction while rotating the chuck 300, and the moving average value or the moving median value of the thicknesses measured at the multiple points in the circumferential direction is calculated. The total thickness Ht (distribution of the total thickness Ht) of the combined wafer T measured in this way is outputted to the control device 110.

Upon the completion of the alignment in the process E2 and the thickness measurement in the processes E3 and E4 as described above, the chuck 300 is moved to the carry-in/out position, as shown in FIG. 16F. At this time, by rotating the chuck 300, the position of the upper wafer W in the horizontal direction measured in the process E2 is aligned to a required position.

In the control device 110, the thickness Hs of the lower wafer S is calculated by subtracting the thickness Hw of the upper wafer W measured in the process E3 from the thickness Ht of the combined wafer T measured in the process E4 (process E5 in FIG. 15). This thickness Hs includes the thickness of the lower wafer S, the thicknesses of the device layers Dw and Ds, and the thicknesses of the surface films Fw and Fs, as stated above. The thickness Hs of the lower wafer S is calculated at each of the measurement points P1, P2 and P3, so that the distribution of the thickness Hs of the lower wafer S is obtained.

Furthermore, the control device 110 controls, based on the distribution of the thickness Hs of the lower wafer S calculated in the process E5, the inclination adjusting unit 74 at the processing position A3 of the processing apparatus 70. Specifically, based on the distribution of the thickness Hs of the lower wafer S, the parallelism between the surface of the chuck 72 and the surface of the finishing grinding wheel 101 is adjusted so that the in-surface thickness of the upper wafer W, which is bonded to the lower wafer S, after being subjected to the finishing grinding becomes uniform (process E6 in FIG. 15). In the following description, the adjustment of the parallelism between the surface of the chuck 72 and the surface of the finishing grinding wheel 101 may be referred to as tilt correction.

Next, the second shutter 360 of the first thickness measuring apparatus 52 is opened, and the combined wafer T is transferred to the processing apparatus 70 by the wafer transfer device 60 and is then delivered to the chuck 72 at the delivery position A0. At this time, since the internal pressure of the first thickness measuring apparatus 52 is controlled to be higher than the internal pressure of the second processing block G2, the particles or the like are suppressed from being introduced from the processing apparatus 70 into the first thickness measuring apparatus 52.

Thereafter, the rotary table 71 is rotated to move the combined wafer T to the processing position A1. Then, the rear surface Wb of the upper wafer W is roughly ground by the rough grinding unit 80 (process E7 in FIG. 15). At this time, the upper wafer W is ground to a required thickness while measuring the total thickness Ht of the combined wafer T by using a contact type thickness measuring device (not shown).

Subsequently, the rotary table 71 is rotated to move the combined wafer T to the processing position A2. Then, the rear surface Wb of the upper wafer W is ground to an intermediate level by the intermediate grinding unit 90 (process E8 in FIG. 15). At this time, the upper wafer W is ground while measuring the total thickness Ht of the combined wafer T by using a contact type thickness measuring device (not shown), and then, the upper wafer W is ground while measuring the thickness Hw of the upper wafer W by using a non-contact type thickness measuring device (not shown).

Next, the rotary table 71 is rotated to move the combined wafer T to the processing position A3. Then, the rear surface Wb of the upper wafer W is finely ground by the finishing grinding unit 100 (process E9 in FIG. 15). In this finishing grinding, the chuck 72 and the finishing grinding wheel 101 after being subjected to the tilt correction in the process E6 are used. Furthermore, here, the upper wafer W is ground to a required thickness while measuring the thickness Hw of the upper wafer W by using a non-contact type thickness measuring device (not shown).

Thereafter, the rotary table 71 is rotated to move the combined wafer T to the delivery position A0. At the delivery position A0, the rear surface Wb of the upper wafer W after being ground may be cleaned by a cleaning unit (not shown).

The combined wafer T after being subjected to the processing in the processing apparatus 70 is then transferred to the second cleaning apparatus 51 by the wafer transfer device 60. In the second cleaning apparatus 51, the same cleaning as in the process E1 is performed. That is, by supplying the cleaning liquid to the rear surface Wb of the upper wafer W while rotating the combined wafer T, the rear surface Wb is cleaned by spinning, and by supplying the cleaning liquid while keeping the cleaning brush (not shown) in contact with the rear surface Sb of the lower wafer S, the rear surface Sb is scrub-cleaned (process E10 in FIG. 15).

Then, the first shutter 350 of the second thickness measuring apparatus 53 is opened, and the combined wafer T is transferred to the second thickness measuring apparatus 53 by the wafer transfer device 40. At this time, since the internal pressure of the second thickness measuring apparatus 53 is controlled to be lower than the internal pressure of the first processing block G1, the first processing block G1 as the clean space is suppressed from being contaminated as a result of opening the first shutter 350. In the second thickness measuring apparatus 53, the combined wafer T is attracted to and held by the chuck 400 at a carry-in/out position (home position).

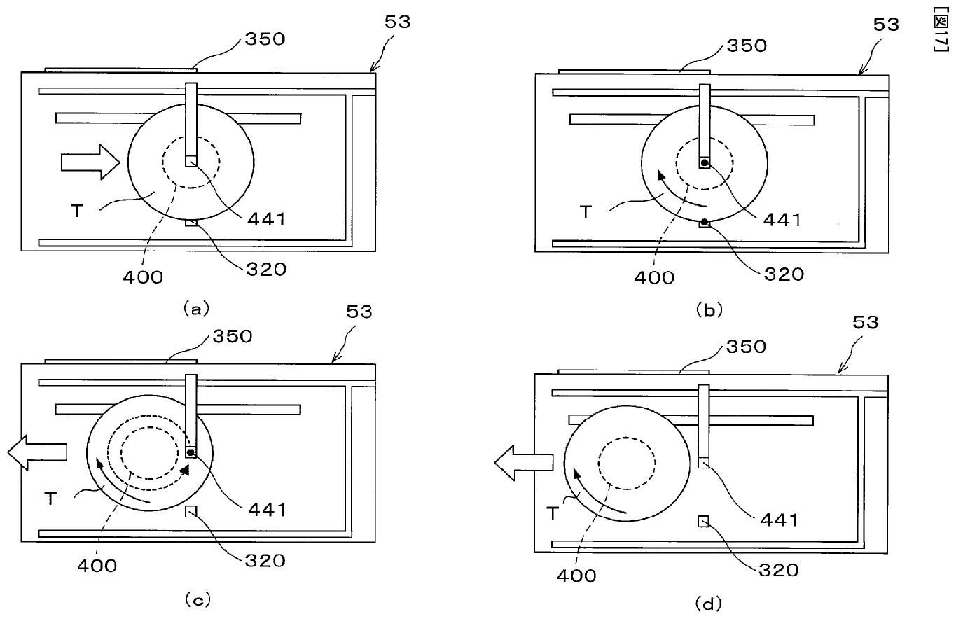

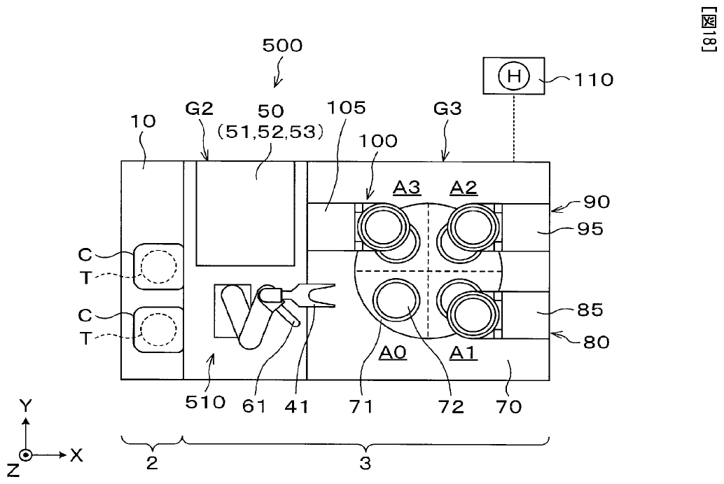

Subsequently, the chuck 400 is moved to an alignment position as shown in FIG. 17A. Then, as illustrated in FIG. 17B, while rotating the combined wafer T, the position of the combined wafer T in the horizontal direction is detected by the position detection unit 320, and the position (eccentric amount) of the center of the upper wafer W is also detected. Based on this detection result, the direction of the combined wafer T in the horizontal direction is adjusted (0 alignment), and the position in the horizontal direction is also adjusted (X-Y alignment) (process E11 in FIG. 15).

Further, at the alignment position, the thickness Hw of the upper wafer W after being ground is measured by the partial thickness measurement unit 440 by the method shown in FIG. 11A to FIG. 11C (process E12 in FIG. 15). That is, the thickness Hw at the center (measurement point P1) of the upper wafer W is first measured. In the measurement of the thickness Hw of the upper wafer W at the measurement point P1, the chuck 400 (combined wafer T) may be rotated or the rotation thereof may be stopped. In addition, the measurement of the thickness Hw of the upper wafer W at the measurement point P1 may be performed simultaneously with the detection (process E11) of the position of the combined wafer T in the horizontal direction.

Subsequently, as depicted in FIG. 17C, by sequentially performing the movement of the chuck 400 to the negative Y-axis side and the rotation of the chuck 400, the thickness Hw of the upper wafer W is measured at the multiple points (measurement points P2 and P3) in the radial direction of the upper wafer W. In the measurement of the thickness Hw of the upper wafer W at the measurement points P2 and P3, the thickness Hw of the upper wafer W is measured at multiple points in the circumferential direction while rotating the chuck 400, and the moving average value or the moving median value of the thicknesses of the measured points in the circumferential direction is calculated. The thickness Hw (distribution of the thickness Hw) of the upper wafer W measured in this way is outputted to the control device 110.

Upon the completion of the alignment in the process E11 and the measurement of the thickness Hw of the upper wafer W in the process E12 as described above, the chuck 400 is moved to the carry-in/out position, as shown in FIG. 17D. At this time, by rotating the chuck 400, the position of the combined wafer T in the horizontal direction measured in the process E11 is aligned to a required position.

The control device 110 controls the inclination adjusting unit 74 at the processing position A3 of the processing apparatus 70 based on the distribution of the thickness Hw of the upper wafer W measured in the process E12. Specifically, based on the distribution of the thickness Hw of the upper wafer W after being ground, the parallelism between the surface of the chuck 72 and the surface of the finishing grinding wheel 101 is adjusted so that the in-surface thickness of a next upper wafer W, which is to be processed next, after being subjected to the finishing grinding becomes uniform (process E13 in FIG. 15). That is, in the process E13, the parallelism between the surface of the chuck 72 and the surface of the finishing grinding wheel 101 is adjusted at the processing position A3 after performing the processes E1 to E12 on the n^{th} (n is an integer equal to or larger than 1) sheet of combined wafer T, in order to perform the grinding of the (n+1)^{th} sheet of combined wafer T (upper wafer W).

Next, the second shutter 360 of the second thickness measuring apparatus 53 is opened, and the combined wafer T is transferred to the etching apparatus 30 by the wafer transfer device 40. In the etching apparatus 30, a wet etching processing (cleaning processing) is performed on the rear surface Wb of the upper wafer W and the rear surface Sb of the lower wafer S (process E14 in FIG. 15).

Thereafter, the combined wafer T after being subjected to all the required processes is transferred to the cassette C of the cassette placing table 10 by the wafer transfer device 40. In this way, the series of processes of the wafer processing in the wafer processing system 1 are completed.

Further, in the wafer processing system 1, the processing for the n^{th} sheet of combined wafer T and the processing for the (n+1)^{th} sheet of combined wafer T may be performed in parallel. In this case, the processes E1 to E12 are performed on the n^{th} sheet of combined wafer T, and the tilt correction for the grinding of the (n+1)^{th} sheet of upper wafer W is performed in the process E13. Meanwhile, the processes E1 to E5 are performed on the (n+1)^{th} sheet of combined wafer T, and the tilt correction for the grinding of the (n+1)^{th} sheet of upper wafer W is performed in the process E6. In this way, in the n^{th} process E13 and the (n+1)^{th} process E6, the tilt correction for the grinding of the same (n+1)^{th} sheet of upper wafer W is performed. Therefore, in this case, the parallelism between the surface of the chuck 72 and the surface of the finishing grinding wheel 101 at the processing position A3 is adjusted based on the thickness Hw of the n^{th} sheet of upper wafer W measured in the process E12 and the thickness Hs of the (n+1)^{th} sheet of lower wafer S calculated in the process E5.

According to the above-described exemplary embodiment, the measurement of the thickness Hw of the upper wafer W before and after being subjected to the grinding in the processing apparatus 70 is performed by using the first thickness measuring apparatus 52 and the second thickness measuring apparatus 53 provided independently outside the processing apparatus 70, respectively. Therefore, compared to the case where the thickness measurement is performed in the processing apparatus 70 as in the prior art, the wafer processing time in the processing apparatus 70 can be shortened in the present exemplary embodiment. As a result, the throughput of the wafer processing can be improved.

In addition, since the first thickness measuring apparatus 52 and the second thickness measuring apparatus 53 are provided independently of other processing apparatuses in the wafer processing system 1 as stated above, they do not affect the wafer processing time in another processing apparatus in the processing apparatus 70 (for example, the first cleaning apparatus 50 or the second cleaning apparatus 51). As a result, the throughput of the wafer processing can be further improved.

Further, in the present exemplary embodiment, since the parallelism between the surface of the chuck 72 and the surface of the finishing grinding wheel 101 is adjusted in the process E13 based on the thickness Hw of the upper wafer W measured in the process E12, the in-surface thickness of the next upper wafer W after being subjected to the finishing grinding can be made uniform.

Further, in the present exemplary embodiment, the measurement (process E3) of the thickness Hw of the upper wafer W before being ground and the measurement (process E4) of the total thickness Ht of the combined wafer T before being ground are performed by the first thickness measuring apparatus 52. In this way, since the two thickness measurements before the grinding are respectively performed in the one and the same apparatus, the wafer processing time in the wafer processing system 1 can be further shortened, so that the throughput can be further improved.

Furthermore, in the present exemplary embodiment, since the parallelism between the surface of the chuck 72 and the surface of the finishing grinding wheel 101 is adjusted in the process E6 based on the thickness Hs of the lower wafer S calculated in the process E5, the in-surface thickness of the upper wafer W after being subjected to the finishing grinding can be made uniform.

Moreover, in the present exemplary embodiment, the measurement of the thickness Hw in the process E3, the measurement of the total thickness Ht in the process E4, and the measurement of the thickness Hw in the process E12 are performed at the same measurement points P1, P2, and P3. For this reason, the parallelism between the surface of the chuck 72 and the surface of the finishing grinding wheel 101 can be properly adjusted.

Further, in the present exemplary embodiment, in the first thickness measuring apparatus 52 and the second thickness measuring apparatus 53, the position detection units 320 and the sensors 341 and 441 of the partial thickness measurement units 340 and 440 are provided at the same positions in the Y-axis direction (driving direction of the chucks 300 and 400). Accordingly, the detection of the position in the horizontal direction by the position detection units 320 and the measurement of the thickness Hw at the center of the upper wafer W by the partial thickness measurement units 340 and 440 can be performed at the same position. Therefore, the wafer processing time in the first thickness measuring apparatus 52 and the second thickness measuring apparatus 53 can be shortened.

In addition, in the present exemplary embodiment, in the wafer processing system 1, the internal pressures of the first to third processing blocks G1 to G3 are controlled to be higher in this order, and the internal pressure of the first thickness measuring apparatus 52 is controlled to be lower than the internal pressure of the first processing block G1 and higher than the internal pressure of the third processing block G3. In other words, in the wafer processing system 1, the airflow flowing from the first processing block G1 to the second and third processing blocks G2 and G3 in sequence via the first thickness measuring apparatus 52 is formed. As a result, the particles or the like generated in the processing apparatus 70 of the third processing block G3 are suppressed from being introduced into the first processing block G1 as the clean space or the first thickness measuring apparatus 52. That is, the combined wafer T after being subjected to the series of processes in the wafer processing system 1 can be suppressed from being contaminated.

Further, in the present exemplary embodiment, there is no timing when the first shutter 350 and the second shutter 360 of the first thickness measuring apparatus 52 are opened simultaneously in the series of processes of the wafer processing. In other words, since the first processing block G1 and the second processing block G2 do not communicated with each other directly in the alignment and the thickness measurement of the combined wafer T, the introduction of the particles or the like into the first processing block G1 can be further suppressed.

In the present exemplary embodiment, the transfer of the combined wafer T by the wafer transfer device 60 is not performed with respect to the second thickness measuring apparatus 53 configured to measure the thickness of the upper wafer W after being ground by the processing apparatus 70, and the second thickness measuring apparatus 53 is not provided with the second shutter 360. With this configuration, since the second processing block G2, which communicates with the processing apparatus 70, do not communicate with the second thickness measuring apparatus 53, the contamination of the combined wafer T after being subjected to the series of processes can be further suppressed.

In the above-described exemplary embodiment, the cleaning of the combined wafer T is performed prior to the alignment of the combined wafer T, as shown in the processes E1 and E10 of FIG. 15. However, the cleaning of the combined wafer T may be appropriately omitted.

Moreover, in the above-described exemplary embodiment, the alignment of the combined wafer T after being ground is performed in the second thickness measuring apparatus 53, as shown in the process E11 of FIG. 15. However, when there occurs no deviation in the position of the combined wafer T in the horizontal direction during, for example, the grinding processes (processes E7 to E9) or during the transfer of the combined wafer T, the alignment of the combined wafer T may be omitted.

Additionally, in the above-described exemplary embodiment, the cleaning of the combined wafer T is performed prior to the alignment thereof, as shown in the processes E1 and E2 and the processes E10 and E11 in FIG. 15. However, the order of the cleaning and the alignment of the combined wafer T may be reversed. In this case, the alignment of the combined wafer T may be performed inside the thickness measuring apparatus, or an aligning apparatus configured to perform the alignment of the combined wafer T may be further provided outside the thickness measuring apparatus.

Further, when the order of the cleaning (processes E1 and E10) and the alignment (processes E2 and E11) of the combined wafer T is reversed in this way, as described above, there may be adopted a configuration in which the combined wafer T can be transferred to the first cleaning apparatus 50 and the second thickness measuring apparatus 53 by the wafer transfer device 60. In other words, the second thickness measuring apparatus 53 may be equipped with the second shutter 360 for allowing the transfer of the combined wafer T to/from the wafer transfer device 60.

Furthermore, in the above-described exemplary embodiment, in order to collect the information (thickness) required for the tilt correction at the processing position A3, the partial thickness measurement units 340 and 440 are provided in each of the first thickness measuring apparatus 52 and the second thickness measuring apparatus 53, and the total thickness measurement unit 330 is provided in the first thickness measuring apparatus 52. However, the information (thickness) for purposes other than the tilt correction may be collected.

In the above-described exemplary embodiment, the thickness measurement is performed at the three points (measurement points P1, P2, and P3) in the radial direction of the combined wafer T (upper wafer W) in the processes E3, E4, and E12. However, the number of the measurement points P may be more than three. With the larger number of measurement points, the distributions of the thickness Hw of the upper wafer W and the thickness Hs of the lower wafer S can be appropriately investigated, and, as a result, the parallelism between the surface of the chuck 72 and the surface of the finishing grinding wheel 101 in the process E6 can be appropriately adjusted.

Moreover, the position of the measurement point of the thickness Hw of the upper wafer W is not limited to the example of the present exemplary embodiment. For instance, when a position where unevenness occurs in the thickness Hw of the upper wafer W after being ground, that is, a singularity is known in advance, this singularity may be used as the measurement point for the thickness Hw. Further, the thickness Hw of the upper wafer W at the singularity may be further measured after the thickness measurement at the measurement points P1 to P3 in the process E12, for example.

Specifically, in case of measuring the thickness Hw of the upper wafer W at the singularity in the second thickness measuring apparatus 53, for example, the chuck 400 (combined wafer T) is rotated and also moved in the horizontal direction in the state that the combined wafer T is held by the chuck 400, thus allowing the singularity to be moved to directly under the sensor 441 of the partial thickness measurement unit 440. Accordingly, the thickness Hw of the upper wafer W is measured by the partial thickness measurement unit 440. In addition, when a plurality of singularities are formed in the surface of the upper wafer W, the thickness measurements at the respective singularities can be sequentially performed by repeating the rotation and the movement of the chuck 400 (combined wafer T).

In addition, in the case of measuring the thickness Hw of the upper wafer W at the singularity in the second thickness measuring apparatus 53 in this way, the installation position of the second thickness measuring apparatus 53 is not limited to the present exemplary embodiment. Since this measurement may be performed after the wet etching processing in the process E14, the second thickness measuring apparatus 53 may be provided in, for example, the first processing block G1 or the like.

In the above-described exemplary embodiment, the wafer processing system 1 has the configuration in which the carry-in/out station 2 and the first to third processing blocks G1 to G3 are arranged in this order in the X-axis direction, as illustrated in FIG. 2 and FIG. 3. However, the configuration of the wafer processing system 1 is not limited thereto.

Specifically, as in a wafer processing system 500 according to another exemplary embodiment shown in FIG. 18, the first processing block G1 may be omitted. More specifically, as in the wafer processing system 500, the etching apparatus 30 and the wafer transfer device 40 may be omitted, and the combined wafer T after being ground may be subjected to an etching processing at the outside of the wafer processing system 500. In this case, the second processing block G2 is equipped with a wafer transfer device 510 configured to transfer the combined wafer T to/from the cassette C of the cassette placing table 10, the first cleaning apparatus 50, the second cleaning apparatus 51, the first thickness measuring apparatus 52, the second thickness measuring apparatus 53, and the processing apparatus 70.

In this case, the wafer transfer device 510 has a transfer arm 41 capable of transferring the combined wafer T to/from the cassette C; and a transfer arm 61 capable of transferring the combined wafer T to/from the first cleaning apparatus 50, the second cleaning apparatus 51, the first thickness measuring apparatus 52, the second thickness measuring apparatus 53, and the processing apparatus 70. The transfer arm 41 is configured to hold and transfer the combined wafer T, and the transfer arm 61 has an attracting/holding surface (not shown).

In addition, since the wafer transfer device 40 is omitted in the wafer processing system 500 as described above, the combined wafer T is transferred to the first cleaning apparatus 50, the second cleaning apparatus 51, the first thickness measuring apparatus 52, and the second thickness measuring apparatus 53 only by the wafer transfer device 60. In other words, in the first thickness measuring apparatus 52 and the second thickness measuring apparatus 53 of the wafer processing system 500, the first shutter 350 and the driving mechanism 351 on the later side on the negative X-axis side is omitted, and the second shutter 360 and the driving mechanism 361 on the later side on the negative Y-axis side are provided.

In addition, two transfer arms 61 may be provided in the wafer transfer device 510. One transfer arm 61 configured to transfer the combined wafer T before being ground and the other transfer arm 61 configured to transfer the combined wafer T after being ground may be separately used.

It should be noted that the exemplary embodiments described so far are illustrative in all aspects and are not anyway limiting. The above-described exemplary embodiments may be omitted, replaced and modified in various ways without departing from the scope and the spirit of claims.

### EXPLANATION OF CODES

1: Wafer processing system
52: First thickness measuring apparatus
53: Second thickness measuring apparatus
Processing apparatus
Ht: Total thickness
Hw: Thickness (of upper wafer)
S: Lower wafer
T: Combined wafer
W: Upper wafer

1. A substrate processing system configured to process a combined substrate in which a first substrate and a second substrate are bonded to each other, the substrate processing system comprising:
a processing apparatus configured to grind the first substrate;
a first thickness measuring apparatus configured to measure a thickness of the first substrate before being ground by the processing apparatus and a total thickness of the combined substrate including the first substrate; and
a second thickness measuring apparatus configured to measure the thickness of the first substrate after being ground by the processing apparatus.

2. The substrate processing system of claim 1,
wherein the first thickness measuring apparatus comprises:
a first substrate holder configured to hold the combined substrate;
a first measurement unit configured to measure the thickness of the first substrate held by the first substrate holder; and
a total thickness measurement unit configured to measure the total thickness of the combined substrate held by the first substrate holder,
wherein the first substrate holder is provided with a notch extending from a center of the first substrate holder to an outer end thereof in a radial direction, and the total thickness measurement unit is allowed to be advanced into or retreated from the notch, and
wherein the second thickness measuring apparatus comprises:
a second substrate holder configured to hold the combined substrate; and
a second measurement unit configured to measure the thickness of the first substrate held by the second substrate holder.

3. The substrate processing system of claim 2,
wherein a diameter of the first substrate holder is smaller than a diameter of the second substrate holder.

4. The substrate processing system of claim 2,
wherein the first thickness measuring apparatus comprises:
a first driving unit configured to move and rotate the first substrate holder in a horizontal direction; and
a first position detection unit configured to detect a position of the combined substrate before being ground by the processing apparatus in the horizontal direction, and
wherein the first position detection unit is disposed at a same position as the first measurement unit in a moving direction of the first substrate holder.

5. The substrate processing system of claim 2,
wherein the second thickness measuring apparatus comprises:
a second driving unit configured to move and rotate the second substrate holder in a horizontal direction; and
a second position detection unit configured to detect a position of the combined substrate after being ground in the horizontal direction, and
wherein the second position detection unit is disposed at a same position as the second measurement unit in a moving direction of the second substrate holder.

6. The substrate processing system of claim 1, further comprising:
a first substrate transfer device configured to transfer the combined substrate to/from a cassette, the combined substrate including multiple combined substrates and the cassette being allowed to accommodate therein the multiple combined substrates; and
a second substrate transfer device configured to transfer the combined substrate to/from the processing apparatus,
wherein the first thickness measuring apparatus is provided with a first transfer opening through which the first substrate transfer device is advanced, and a second transfer opening through which the second substrate transfer device is advanced, and
the second thickness measuring apparatus is provided with a first transfer opening through which the first substrate transfer device is advanced, and is not provided with a second transfer opening through which the second substrate transfer device is advanced.

7. The substrate processing system of claim 1, further comprising:
a carry-in/out section in which the cassette is placed, the combined substrate including multiple combined substrates and the cassette being allowed to accommodate therein the multiple combined substrates;
a processing section in which the first thickness measuring apparatus and the second thickness measuring apparatus are disposed;
a machining section in which the processing apparatus is disposed; and
a control device configured to control an internal pressure of the carry-in/out section to be higher than an internal pressure of the processing section, and, also, control the internal pressure of the processing section to be higher than an internal pressure of the machining section.

8. The substrate processing system of claim 7,
wherein the control device controls an internal pressure of the first thickness measuring apparatus and an internal pressure of the second thickness measuring apparatus to be lower than the internal pressure of the carry-in/out section and higher than the internal pressure of the processing section.

9. The substrate processing system of claim 1, further comprising:
a first cleaning apparatus configured to clean the combined substrate before being ground by the processing apparatus; and
a second cleaning apparatus configured to clean the combined substrate after being ground by the processing apparatus,
wherein the first cleaning apparatus, the second cleaning apparatus, the first thickness measuring apparatus, and the second thickness measuring apparatus are arranged to be stacked.

10. A substrate processing method of processing, in a substrate processing system, a combined substrate in which a first substrate and a second substrate are bonded to each other, the substrate processing method comprising:
measuring, with a first thickness measuring apparatus, a thickness of the first substrate before being ground;
measuring, with the first thickness measuring apparatus, a total thickness of the combined substrate before being ground;
grinding the first substrate with a processing apparatus; and
measuring, with a second thickness measuring apparatus, the thickness of the first substrate after being ground.

11. The substrate processing method of claim 10, further comprising:
calculating a thickness of the second substrate based on the total thickness of the combined substrate before being ground and the thickness of the first substrate before being ground; and
adjusting, prior to the grinding of the first substrate, a relative inclination between a holding surface of a third substrate holder of the processing apparatus, the combined substrate being held on the holding surface, and a grinding surface of a grinding whetstone, based on the calculated thickness of the second substrate.

12. The substrate processing method of claim 10,
wherein the combined substrate includes multiple combined substrates,
the multiple combined substrates are sequentially processed in the substrate processing system, and
prior to grinding of the first substrate in a combined substrate to be processed next, a relative inclination between a holding surface of a third substrate holder of the processing apparatus, the combined substrate being held on the holding surface, and a grinding surface of a grinding whetstone is adjusted based on the thickness of the first substrate after being ground.

13. The substrate processing method of claim 10, further comprising:
detecting, with the first thickness measuring apparatus, a position of the combined substrate before being ground in a horizontal direction; and
detecting, with the second thickness measuring apparatus, a position of the combined substrate after being ground in the horizontal direction.

14. The substrate processing method of claim 13,
wherein, in the first thickness measuring apparatus and the second thickness measuring apparatus, the thickness of the first substrate is measured at multiple points in a radial direction, and
the thickness at a center of the first substrate is measured at a same position where the detecting of the position of the combined substrate in the horizontal direction is performed.

15. The substrate processing method of claim 10,
wherein the substrate processing system comprises:
a first substrate transfer device configured to transfer the combined substrate to/from a cassette, the combined substrate including multiple combined substrates and the cassette being allowed to accommodate therein the multiple combined substrates; and
a second substrate transfer device configured to transfer the combined substrate to/from the processing apparatus,
wherein the first substrate transfer device and the second substrate transfer device are advanced into the first thickens measuring apparatus, and
only the first substrate transfer device is advanced into the second thickness measuring apparatus whereas the second substrate transfer device is not advanced thereinto.

16. The substrate processing method of claim 10,
wherein the substrate processing system comprises:
a carry-in/out section in which the cassette is placed, the combined substrate including multiple combined substrates and the cassette being allowed to accommodate the multiple combined substrates;
a processing section in which the first thickness measuring apparatus and the second thickness measuring apparatus are disposed; and
a machining section in which the processing apparatus is disposed, and
wherein an internal pressure of the carry-in/out section is controlled to be higher than an internal pressure of the processing section, and the internal pressure of the processing section is controlled to be higher than an internal pressure of the machining section.

17. The substrate processing method of claim 16,
wherein an internal pressure of the first thickness measuring apparatus and an internal pressure of the second thickness measuring apparatus are controlled to be lower than the internal pressure of the carry-in/out section and higher than the internal pressure of the processing section.

18. The substrate processing method of claim 10, further comprising:
cleaning, with a first cleaning apparatus, the combined substrate before being ground, prior to the measuring of the thickness of the first substrate with the first thickness measuring apparatus; and
cleaning, with a second cleaning apparatus, the combined substrate after being ground, prior to the measuring of the thickness of the first substrate with the second thickness measuring apparatus.
